(19) United States
(12) Patent Application Publication
(10) Pub. No.: US 2021/0144865 A1
(43) Pub. Date: May 13, 2021

(54) SCREW ATTACHMENT MEMBER AND DISPLAY APPARATUS

(71) Applicant: SHARP KABUSHIKI KAISHA, Osaka (JP)

(72) Inventors: TATSUYA TERASHIMA, Osaka (JP); MASAYUKI KIHARA, Osaka (JP)

(21) Appl. No.: 16/903,320

(22) Filed: Jun. 16, 2020

(30) Foreign Application Priority Data
Nov. 7, 2019 (JP) 2019-202296

(51) Int. Cl. H05K 5/00; F16B 5/02; G02F 1/1333

(52) U.S. Cl. CPC H05K 5/0008; F16B 5/0241; H04N 5/64; G02F 1/133308; H05K 5/0017

(57) ABSTRACT

A screw attachment member includes a structure in which an insertion hole through which a screw passes and an opening are formed. In the structure, a peripheral edge portion of the insertion hole is in contact with a bearing surface of a head portion of the screw. The insertion hole is formed so that a distance between an inner peripheral surface and a central axis of the insertion hole varies in a circumferential direction. The opening is formed in a periphery of a proximal portion in the insertion hole at which a distance between the inner peripheral surface and the central axis is shorter than an average.

### BACKGROUND

### 1. Field

The present disclosure relates to a screw attachment member and a display apparatus.

### 2. Description of the Related Art

A printed circuit board that has a plurality of screw holes has been conventionally disclosed (refer to Japanese Unexamined Patent Application Publication No. 2016-162944, for example).

In a printed circuit board (screw attachment member) described in Japanese Unexamined Patent Application Publication No. 2016-162944, a slit is formed to partially surround a screw hole formed in the vicinity of an outer edge of the printed circuit board. The slit is formed so as to surround the screw hole.

In Japanese Unexamined Patent Application Publication No. 2016-162944, a screw-fixing region that is formed in a portion partially surrounded by the slit is coupled, by a coupling portion at one place only, to a printed circuit board outer edge region, which is on a side across from the slit. Accordingly, in Japanese Unexamined Patent Application Publication No. 2016-162944, there is a possibility that strength of the printed circuit board is reduced.

The disclosure provides a screw attachment member capable of suppressing strength from being reduced and suppressing deformation caused by screw stress from occurring, and a display apparatus.

### SUMMARY

A screw attachment member according to a first aspect includes a structure in which an insertion hole through which a screw passes and an opening are formed. In the structure, a peripheral edge portion of the insertion hole is in contact with a bearing surface of a head portion of the screw. The insertion hole is formed so that a distance between an inner peripheral surface and a central axis of the insertion hole varies in a circumferential direction. The opening is formed in a periphery of a proximal portion in the insertion hole at which a distance between the inner peripheral surface and the central axis is shorter than an average.

A display apparatus according to a second aspect includes: the screw attachment member according to the first aspect; a display unit that includes a display surface, on which an image is displayed, on a front surface and has a rectangular plate shape; and a chassis that supports the display unit from a back side. The screw attachment member is a cabinet surrounding the display unit and is fixed to the chassis by the screw.

### BRIEF DESCRIPTION OF THE DRAWINGS

FIG. 1 is a perspective view of an external appearance of a display apparatus according to an embodiment;

FIG. 2 is an exploded perspective view of the display apparatus;

FIG. 3 is a rear view of the display apparatus;

FIG. 4 is an enlarged rear view of a central upper part in the display apparatus;

FIG. 5 is a sectional view taken along line V-V of FIG. 4;

FIG. 6 is an enlarged view of an insertion hole and an opening that are formed in a cabinet in the display apparatus;

FIG. 7A illustrates a simulation result of screw stress generated in the cabinet, and FIG. 7B illustrates a simulation result of screw stress generated in a cabinet of a comparative example;

FIG. 8 is a graph of flatness of the cabinet;

FIG. 9A is a schematic view of a first modified example of the insertion hole, FIG. 9B is a schematic view of a second modified example of the insertion hole, and FIG. 9C is a schematic view of a third modified example of the insertion hole;

FIG. 10A is a schematic view of a first modified example of the opening, FIG. 10B is a schematic view of a second modified example of the opening, and FIG. 100 is a schematic view of a third modified example of the opening;

FIG. 11A is a schematic view of a fourth modified example of the opening, and FIG. 11B is a schematic view of a fifth modified example of the opening;

FIG. 12A is a schematic view of a sixth modified example of the opening, FIG. 12B is a schematic view of a seventh modified example of the opening, and FIG. 12C is a schematic view of an eighth modified example of the opening;

FIG. 13A is a schematic view of a ninth modified example of the opening, and FIG. 13B is a schematic view of a tenth modified example of the opening;

FIG. 14A is a schematic view of an eleventh modified example of the opening, and FIG. 14B is a sectional view taken along line XIVB-XIVB of FIG. 14A;

FIG. 15A is a schematic view of a first modified example of a structure, and FIG. 15B is a sectional view taken along line XVB-XVB of FIG. 15A; and

FIG. 16 is a schematic view of a second modified example of the structure.

### DESCRIPTION OF THE EMBODIMENTS

An embodiment and modified examples described below are merely examples of the disclosure, and the disclosure is not limited by the embodiment or the modified examples. In addition to the embodiment and the modified examples, various modifications are allowed in accordance with the design and the like within a range not departing from the technical gist of the disclosure.

### Embodiment

### (1) Outline

A display apparatus 1 of the present embodiment will be described with reference to FIGS. 1 to 6.

The display apparatus 1 of the present embodiment is a display apparatus that displays an image such as a moving image or a still image. In the present embodiment, the display apparatus 1 includes a receiving circuit that receives a television broadcast signal from an antenna, a display circuit that causes a video based on the received television broadcast signal to be displayed, and the like, and functions additionally as a television receiver.

As illustrated in FIG. 2, the display apparatus 1 includes a display unit 2, a chassis 3, a bezel 4, and a cabinet 5.

The display unit 2 is formed to have a rectangular plate shape and has a display surface 21, on which an image is displayed, on a front surface. The chassis 3 is formed to support the display unit 2 from the back. The bezel 4 is formed into a frame and formed to surround the display unit 2. The cabinet 5 is formed to surround the display unit 2 from outside the bezel 4 and is fixed to the chassis 3 by a screw 7.

In the present embodiment, the cabinet 5 is a screw attachment member to which the screw 7 is attached. The cabinet 5 is referred to as the screw attachment member 5 in the description below in some cases.

The screw attachment member 5 includes a structure 60, an insertion hole 61, and an opening 62. The insertion hole 61 is formed in the structure 60, and the screw 7 is passed therethrough. The opening 62 is formed in the structure 60.

A peripheral edge portion 601 of the insertion hole 61 of the structure 60 comes into contact with a bearing surface 711 of a head portion 71 of the screw 7. In the insertion hole 61, the distance between an inner peripheral surface 611 and a central axis A1 of the insertion hole 61 varies in the circumferential direction. The opening 62 is formed in a periphery of a proximal portion 612A of the insertion hole 61 at which a distance between the inner peripheral surface 611 and the central axis A1 is shorter than an average.

The screw attachment member 5 (cabinet 5) is fixed to the chassis 3 by the screw 7. When the screw attachment member 5 is screwed to the chassis 3, the screw 7 is rotated in a state where the bearing surface 711 of the screw 7 is in contact with the peripheral edge portion 601 of the insertion hole 61 so that stress (hereinafter, referred to as screw stress) is generated in a periphery of the insertion hole 61, for example, due to friction between the bearing surface 711 and the peripheral edge portion 601. The screw stress is generated so as to be distributed in the peripheral edge portion 601, which is in contact with the bearing surface 711 of the screw 7, as a center. Accordingly, the periphery of proximal portion 612A and the periphery of proximal portion 612B that are closest to the central axis A1 in the insertion hole 61 each have the largest area in which the peripheral edge portion 601 is in contact with the bearing surface 711 and have greater screw stress compared with a portion other than the proximal portions 612A and 612B in the periphery of the insertion hole 61.

In the present embodiment, the opening 62 is formed in the periphery of the proximal portion 612A. Therefore, the opening 62 suppresses the screw stress from transferring to a side of the opening 62 opposite to the insertion hole 61. That is, in the present embodiment, by concentrating the screw stress in the proximal portion 612A and forming the opening 62 in the periphery of the proximal portion 612A, undesirable spread of the screw stress is suppressed from occurring. Thereby, for example, it is possible to suppress strength of the structure 60 from being reduced and to suppress deformation or the like of the structure 60 due to the screw stress from occurring.

### (2) Details

Hereinafter, the display apparatus 1 of the present embodiment will be described in detail with reference to FIGS. 1 to 6. In the description below, description will be given by prescribing that the long-side direction of the display unit 2 is a left-right direction, the short-side direction of the display unit 2 is an up-down direction, and the thickness direction of the display unit 2 is a front-back direction (refer to FIG. 1). However, these directions are prescribed for convenience of the description and do not limit the directions during use.

The display unit 2 is, for example, a display panel and is formed to have a rectangular plate shape. The display unit 2 includes a liquid crystal panel, an optical sheet group, a light-guiding plate, and the like that are arranged sequentially from the front. The light-guiding plate is formed to guide light from a light source, which is provided in the chassis 3, to the optical sheet group. The light from the light source is uniformly radiated by the light-guiding plate and the optical sheet group to a rear surface of the liquid crystal panel. The liquid crystal panel displays an image on the display surface 21 by increasing or decreasing transmittance of the light in accordance with a signal from a video driving circuit.

The chassis 3 is arranged so as to cover the entirety of a rear surface of the display unit 2. The chassis 3 is formed of a metal plate. The chassis 3 includes a back frame portion 31, a peripheral wall portion 32, and a convex portion 33. The back frame portion 31 is formed into a frame having a rectangular shape in which a long-side direction corresponds to the left-right direction, a short-side direction corresponds to the up-down direction, and a thickness direction corresponds to the front-back direction, and is positioned on the back of the display unit 2. The peripheral wall portion 32 protrudes toward the front from an outer peripheral edge of the back frame portion 31 and surrounds an outer periphery of the display unit 2. The convex portion 33 protrudes to the back from an inner peripheral edge of the back frame portion 31, and a tip end surface (back surface) thereof is formed to have a rectangular shape in the up-down direction and the left-right direction. The chassis 3 supports the display unit 2, which is arranged on the front, from the back by using, for example, a screw or the like. Moreover, the chassis 3 further supports the light source which radiates light to the display unit 2, a circuit board in which the receiving circuit and the like are provided, and the like.

The bezel 4 is formed into a frame and is formed so as to surround the outer periphery of the display unit 2. The bezel 4 is formed of a metal plate. The bezel 4 includes a front frame portion 41 and a peripheral wall portion 42.

The front frame portion 41 is formed into a rectangular frame in which a long-side direction corresponds to the left-right direction, a short-side direction corresponds to the up-down direction, and a thickness direction corresponds to the front-back direction, and is arranged so as to extend along an edge of the display surface 21 (front surface) of the display unit 2. Between the front frame portion 41 and the display surface 21 of the display unit 2, for example, a spongy elastic member is provided. The elastic member suppresses contact between the front frame portion 41 and the display surface 21.

The peripheral wall portion 42 protrudes to the back from an outer peripheral edge of the front frame portion 41 and surrounds the outer periphery of the display unit 2 via the peripheral wall portion 32 of the chassis 3. Specifically, the peripheral wall portion 42 includes an upper wall portion 421, a left wall portion 422, a right wall portion 423, and a lower wall portion 424. The upper wall portion 421 is formed to have a rectangular plate shape in which a long-side direction corresponds to the left-right direction, a short-side direction corresponds to the front-back direction, and a thickness direction corresponds to the up-down direction, and extends along an upper side of the display unit 2. The left wall portion 422 is formed to have a rectangular plate shape in which a long-side direction corresponds to the up-down direction, a short-side direction corresponds to the front-back direction, and a thickness direction corresponds to the left-right direction, and extends along a left side of the display unit 2. The right wall portion 423 is formed to have a rectangular plate shape in which a long-side direction corresponds to the up-down direction, a short-side direction corresponds to the front-back direction, and a thickness direction corresponds to the left-right direction, and extends along a right side of the display unit 2. The lower wall portion 424 is formed to have a rectangular plate shape in which a long-side direction corresponds to the left-right direction, a short-side direction corresponds to the front-back direction, and a thickness direction corresponds to the up-down direction, and extends along a lower side of the display unit 2.

The bezel 4 is fixed to the chassis 3. Specifically, the bezel 4 has the peripheral wall portion 42 facing the peripheral wall portion 32 of the chassis 3 and is screwed to the peripheral wall portion 32 of the chassis 3 via an insertion hole formed in the peripheral wall portion 42.

The cabinet 5 is a resin molded article and is formed into a rectangular frame. The cabinet 5 surrounds the outer periphery of the display unit 2 from outside the bezel 4 and is fixed to the chassis 3. The cabinet 5 includes a peripheral wall portion 51, a fixing portion 52, a projecting wall portion 53, and a bottom portion 54.

The peripheral wall portion 51 faces at least a part of an outer peripheral surface of the bezel 4. Specifically, the peripheral wall portion 51 includes an upper wall portion 511, a left wall portion 512, and a right wall portion 513 and faces outer peripheral surfaces of the upper wall portion 421, the left wall portion 422, and the right wall portion 423 in the peripheral wall portion 42 of the bezel 4. The upper wall portion 511 is formed to have a rectangular plate shape in which a long-side direction corresponds to the left-right direction, a short-side direction corresponds to the front-back direction, and a thickness direction corresponds to the up-down direction, and faces an upper surface of the upper wall portion 421 of the bezel 4 in the up-down direction. The left wall portion 512 is formed to have a rectangular plate shape in which a long-side direction corresponds to the up-down direction, a short-side direction corresponds to the front-back direction, and a thickness direction corresponds to the left-right direction, and faces a left surface of the left wall portion 422 of the bezel 4 in the left-right direction. The right wall portion 513 is formed to have a rectangular plate shape in which a long-side direction corresponds to the up-down direction, a short-side direction corresponds to the front-back direction, and a thickness direction corresponds to the left-right direction, and faces a right surface of the right wall portion 423 of the bezel 4 in the left-right direction.

The fixing portion 52 is formed so as to protrude from a back end of the peripheral wall portion 51 toward the inner portion of the peripheral wall portion 51. The fixing portion 52 is positioned on the back of the back frame portion 31 of the chassis 3 and faces the back frame portion 31 in the front-back direction. Specifically, the fixing portion 52 includes an upper fixing portion 521, a left fixing portion 522, and a right fixing portion 523. The upper fixing portion 521 is formed so as to protrude from a back end of the upper wall portion 511 in a downward direction and is formed to have a rectangular plate shape in which a long-side direction corresponds to the left-right direction, a short-side direction corresponds to the up-down direction, and a thickness direction corresponds to the front-back direction. The left fixing portion 522 is formed so as to protrude from a back end of the left wall portion 512 in a right direction and is formed to have a rectangular plate shape in which a long-side direction corresponds to the up-down direction, a short-side direction corresponds to the left-right direction, and a thickness direction corresponds to the front-back direction. The right fixing portion 523 is formed so as to protrude from a back end of the right wall portion 513 in a left direction and is formed to have a rectangular plate shape in which a long-side direction corresponds to the up-down direction, a short-side direction corresponds to the left-right direction, and a thickness direction corresponds to the front-back direction.

The cabinet 5 has the fixing portion 52 facing the back frame portion 31 of the chassis 3 in the front-back direction and is fixed to the chassis 3 by a plurality of screws 7. The fixation of the cabinet 5 and the chassis 3 will be described in detail later.

The projecting wall portion 53 is formed so as to protrude along a peripheral surface of the convex portion 33 of the chassis 3 from an inner peripheral edge of the fixing portion 52 toward the back and covers a part of the peripheral surface of the convex portion 33. Specifically, the projecting wall portion 53 includes an upper projecting wall portion 531, a left projecting wall portion 532, and a right projecting wall portion 533. The upper projecting wall portion 531 is formed so as to protrude along the peripheral surface of the convex portion 33 of the chassis 3 from a lower end of the upper fixing portion 521. The left projecting wall portion 532 is formed so as to protrude along the peripheral surface of the convex portion 33 of the chassis 3 from a right end of the left fixing portion 522. The right projecting wall portion 533 is formed so as to protrude along the peripheral surface of the convex portion 33 of the chassis 3 from a left end of the right fixing portion 523.

In the present embodiment, the cabinet 5 (screw attachment member 5) includes a plurality of structures 60. As the plurality of structures 60, the screw attachment member 5 includes an upper structure 60A, a left structure 60B, and a right structure 60C. The upper structure 60A is constituted by the upper wall portion 511, the upper fixing portion 521, and the upper projecting wall portion 531 that are described above and is formed to have an elongated shape in which a long-side direction corresponds to the left-right direction. The left structure 60B is constituted by the left wall portion 512, the left fixing portion 522, and the left projecting wall portion 532 that are described above and is formed to have an elongated shape in which a long-side direction corresponds to the up-down direction. The right structure 60C is constituted by the right wall portion 513, the right fixing portion 523, and the right projecting wall portion 533 that are described above and is formed to have an elongated shape in which a long-side direction corresponds to the up-down direction.

Note that, the upper structure 60A, the left structure 60B, and the right structure 60C are referred to as the structures 60 when not distinguished from each other. Moreover, in the screw attachment member 5 in the present embodiment, the upper structure 60A, the left structure 60B, and the right structure 60C are integrally formed, but may be separately formed.

The bottom portion 54 is formed so as to be coupled to a lower end portion of the left fixing portion 522 and a lower end portion of the right fixing portion 523 in the fixing portion 52 in the left-right direction. The bottom portion 54 is formed so as to extend along the peripheral surface of the convex portion 33 of the chassis 3 and is screwed to the chassis 3.

Moreover, the display apparatus 1 further includes a cover. The cover is formed to cover the fixing portion 52, the projection wall portion 53, and the bottom portion 54 of the cabinet 5, the convex portion 33 of the chassis 3, and the like from the back.

In this manner, in the display apparatus 1 of the present embodiment, the peripheral wall portion 51 of the cabinet 5 is positioned outside the peripheral wall portion 42 of the bezel 4, and the bezel 4 and the cabinet 5 both surround the display unit 2. The cabinet 5 (screw attachment member 5) is fixed to the chassis 3 by the plurality of screws 7.

The fixation of the cabinet 5 and the chassis 3 will be hereinafter described with reference to FIGS. 3 to 6. Note that for illustration purposes, in the sectional view illustrated in FIG. 5, only the liquid crystal panel of the display unit 2 is illustrated and other constituents are omitted.

In each of the structures 60 in the cabinet 5 (screw attachment member 5), a plurality of insertion holes 61 and a plurality of openings 62 are formed. The screw 7 by which the cabinet 5 is fixed to the chassis 3 passes through each of the insertion holes 61. Moreover, the plurality of openings 62 correspond to the plurality of insertion holes 61 on a one-to-one basis. Each of the openings 62 is formed in the periphery of a corresponding insertion hole 61.

In each of the structures 60, the plurality of insertion holes 61 and the plurality of openings 62 are formed in the long-side direction of the structure 60. Specifically, in the upper fixing portion 521 of the upper structure 60A, the plurality of insertion holes 61 and the plurality of openings 62 are formed in the left-right direction. Moreover, in the left fixing portion 522 of the left structure 60B, the plurality of insertion holes 61 and the plurality of openings 62 are formed in the up-down direction. Further, in the right fixing portion 523 of the right structure 60C, the plurality of insertion holes 61 and the plurality of openings 62 are formed in the up-down direction.

Since the plurality of insertion holes 61 and the plurality of openings 62 that are formed in each of the structures 60 each have a similar configuration, the insertion hole 61 and the opening 62 that are formed in the upper structure 60A will be described in detail with reference to FIG. 6.

The insertion hole 61 passes through the upper fixing portion 521 in the front-back direction and is formed so that the central axis A1 extends in the front-back direction. The insertion hole 61 is an elongated hole in which a long-side direction corresponds to the left-right direction (first direction) that is the long-side direction of the upper structure 60A and in which a short-side direction corresponds to the up-down direction (second direction) that is orthogonal to the left-right direction. The insertion hole 61 is formed so that a left side and a right side curve away from the central axis A1 of the insertion hole 61 and so that an upper side and a lower side are made linear so as to extend in the left-right direction. That is, the insertion hole 61 is formed so that the distance between the inner peripheral surface 611 and the central axis A1 of the insertion hole 61 varies in the circumferential direction. The inner peripheral surface 611 of the insertion hole 61 includes the proximal portions 612A and 612B as portions at each of which a distance between the inner peripheral surface 611 and the central axis A1 is shorter than the average. In the present embodiment, each of the proximal portions 612A and 612B is, in the inner peripheral surface 611 of the insertion hole 61, a portion at which the distance between the inner peripheral surface 611 and the central axis A1 is shortest. The proximal portion 612A is a center portion of the upper side of insertion hole 61 in the left-right direction. The proximal portion 612B is a center portion of the lower side of the insertion hole 61 in the left-right direction.

The insertion hole 61 is formed on a center of the upper structure 60A in the short-side direction (up-down direction). That is, in the upper structure 60A, an upper surface 5110 of the upper wall portion 511 is an end portion that is proximal to the insertion hole 61. Moreover, of the two proximal portions 612A and 612B, the proximal portion 612A is closer to the upper surface 5110.

The opening 62 is a through hole having a slit shape that passes through the upper fixing portion 521 in the front-back direction and is formed in the periphery of the insertion hole 61. Specifically, the opening 62 is formed between the insertion hole 61 and the upper surface 5110 (end portion) of the upper wall portion 511 in the up-down direction. That is, the opening 62 is formed between the proximal portion 612A of the insertion hole 61 and the upper surface 5110 of the upper wall portion 511.

An aperture of the opening 62 has a shape in which a long-side direction corresponds to the left-right direction (first direction) that is the long-side direction of the insertion hole 61 and in which a short-side direction corresponds to the up-down direction (second direction) that is the short-side direction of the insertion hole 61. That is, the opening 62 is an elongated hole in which the long-side direction corresponds to the left-right direction. The opening 62 is formed so that a left side and a right side curve away from a central axis of the opening 62 and an upper side and so that a lower side are made linear so as to extend in the left-right direction. In the left-right direction, an aperture dimension of the insertion hole 61 is set as L1 and an aperture dimension of the opening 62 is set as L2. In the present embodiment, the aperture dimension L2 of the opening 62 is greater than the aperture dimension L1 of the insertion hole 61. Moreover, in the present embodiment, the insertion hole 61 and the opening 62 are formed so that a center of the insertion hole 61 in the left-right direction and a center of the opening 62 in the left-right direction align with each other in the up-down direction.

A boss 34 provided in the chassis 3 passes through the insertion hole 61 from the front. The boss 34 is provided at a position in the back frame portion 31 of the chassis 3 so as to face the insertion hole 61 in the front-back direction. The boss 34 is formed to have a cylindrical shape and is provided so as to protrude rearward from the back frame portion 31. The boss 34 is made of, for example, metal, and fixed to the back frame portion 31 of the chassis 3 by caulking. The boss 34 has a screw groove formed in an inner peripheral surface, and the screw 7 is joined thereto from the back in a state of passing through the insertion hole 61.

The screw 7 includes the head portion 71 and a shaft portion 72. The shaft portion 72 is formed to have a cylindrical shape and has a screw groove formed in an outer peripheral surface. The screw 7 is joined so that the screw groove formed in the outer peripheral surface of the shaft portion 72 and the screw groove formed in the inner peripheral surface of the boss 34 engage each other. The head portion 71 is formed so as to widen from one end portion of the shaft portion 72 and includes the bearing surface 711, which is planer, on a shaft portion 72 side. The external shape of the bearing surface 711 is a round shape in which distances from a center are substantially uniform. The bearing surface 711 comes into contact with the peripheral edge portion 601 of the insertion hole 61.

When rotated with a central axis of the shaft portion 72 as the center, the screw 7 is joined to the boss 34 in a state of passing through the insertion hole 61 so that the central axis of the shaft portion 72 coincides with the central axis A1 of the insertion hole 61. Accordingly, in the periphery of the insertion hole 61, the contact area of the peripheries of the proximal portions 612A and 612B and the bearing surface 711 is larger than the contact area of the other portion and the bearing surface 711.

When the screw 7 is joined to the boss 34, the screw 7 is rotated in a state where the bearing surface 711 of the screw 7 is in contact with the peripheral edge portion 601 of the insertion hole 61. Therefore, screw stress is generated in the periphery of the insertion hole 61, for example, due to the friction between the bearing surface 711 and the peripheral edge portion 601 or the like.

FIG. 7A illustrates a simulation result of screw stress magnitude. In FIG. 7A, the screw stress magnitude is indicated by shading, and the screw stress is greater in a darker part and smaller in a lighter part. Moreover, in FIG. 7A, screw stress contour lines are also illustrated.

The screw stress is generated due to the friction between the bearing surface 711 of the screw 7 and the peripheral edge portion 601 of the insertion hole 61. Therefore, the screw stress is generated so as to be distributed in the peripheral edge portion 601, which is in contact with the bearing surface 711 of the screw 7, as a center. More specifically, the screw stress is generated so as to be distributed in a clockwise direction (rightward rotational direction) from a location at which the peripheral edge portion 601 is in contact with the bearing surface 711 when viewed from a side of the head portion 71 of the screw 7.

In the present embodiment, the insertion hole 61 has a shape in which the long-side direction corresponds to the left-right direction. Thus, in the insertion hole 61, the contact area of the peripheries of the proximal portions 612A and 612B, at each of which the distance between the inner peripheral surface 611 and the central axis A1 is shortest, and the bearing surface 711 is larger than the contact area of the other portions and the bearing surface 711. Therefore, as illustrated in FIG. 7A, in the periphery of the insertion hole 61, the screw stress in the peripheries of the proximal portions 612A and 612B is greater than that of the other portions. Further, the screw stress is generated so as to be distributed from the proximal portions 612A and 612B. That is, in the present embodiment, the insertion hole 61 has a shape in which the long-side direction corresponds to the left-right direction so that the generated screw stress is concentrated in the up-down direction. In other words, the insertion hole 61 is configured so that the screw stress has directivity in the short-side direction of the insertion hole 61.

As a comparative example, FIG. 7B illustrates a simulation result of screw stress magnitude in a case where an insertion hole 61X has a round shape in which distances from a central axis are substantially uniform or is a perfect circle. In the case where the insertion hole 61X is a perfect circle, the bearing surface 711 of the screw 7 is to be substantially uniformly in contact with a peripheral edge portion of the insertion hole 61X. Thus, as illustrated in FIG. 7B, the screw stress is to be generated substantially uniformly in a periphery of the insertion hole 61X.

In the present embodiment, the opening 62 is formed in the periphery of the insertion hole 61. Therefore, the opening 62 suppresses the screw stress from transferring to the side of the opening 62 opposite to the insertion hole 61. Moreover, in the present embodiment, the opening 62 is formed between the proximal portion 612A of the insertion hole 61 and the upper surface 5110 of the upper wall portion 511. Thus, the opening 62 suppresses the screw stress from transferring to the upper wall portion 511 (upper surface 5110). Thereby, deformation of the upper wall portion 511 due to the screw stress is suppressed from occurring.

FIG. 8 illustrates a graph of the flatness of a front end portion of the upper surface 5110 of the upper wall portion 511. In the present disclosure, “flatness” refers to the degree of unevenness (undulation) with respect to a reference position. In FIG. 8, the horizontal axis indicates a position in a predetermined range in the front end portion of the upper surface 5110 in the left-right direction, and the vertical axis indicates a position in the front end portion of the upper surface 5110 in the up-down direction. In FIG. 8, a vertical axis value is 0 in a case where the position of the front end portion of the upper surface 5110 in the up-down direction is at the reference position; that is positive in a case where the position is on an upper side and negative in a case where the position is on a lower side. Moreover, the plurality of insertion holes 61 and the plurality of openings 62 are positioned below the predetermined range of the front end portion of the upper surface 5110 in the left-right direction.

In addition, in FIG. 8, the graph of the flatness of the present embodiment is indicated by Y1 and a graph of flatness of the comparative example is indicated by Y2. In the comparative example, the shape of the insertion hole is a perfect circle or a round shape in which the distances from the central axis are substantially uniform, and no opening 62 is included.

As described above, the opening 62 suppresses the screw stress from transferring to the upper wall portion 511 (upper surface 5110). Accordingly, as illustrated in FIG. 8, in the present embodiment, displacement in the up-down direction is smaller than that in the comparative example, deformation of the upper wall portion 511 is suppressed from occurring.

Moreover, in the present embodiment, the aperture dimension L2 of the opening 62 in the long-side direction is greater than the aperture dimension L1 of the insertion hole 61 in the long-side direction. Thereby, the screw stress is further suppressed from transferring to the upper wall portion 511 (upper surface 5110), and deformation of the upper wall portion 511 is further suppressed from occurring.

Moreover, in the present embodiment, the insertion hole 61 has a shape in which the long-side direction extends in one direction, and thereby the screw stress is concentrated in the proximal portions 612A and 612B, and, furthermore, the opening 62 is formed in the periphery of the proximal portion 612A. Thereby, the opening 62 does not need to be made unnecessarily large, and reduction in strength of the upper structure 60A is able to be suppressed from occurring.

In the present embodiment, similarly to the upper structure 60A, the plurality of insertion holes 61 and the plurality of openings 62 are formed in each of the left structure 60B and the right structure 60C. Thus, deformation of the peripheral wall portion 51 of the cabinet 5, which is externally exposed from the display apparatus 1, is suppressed from occurring, and deterioration in the aesthetics of the display apparatus 1 is suppressed from occurring.

### (3) Modified Examples

Modified examples of the display apparatus 1 of the present embodiment will be described below. In the following description, the same reference sign will be given to a constituent similar to that of the above-described embodiment, and description thereof will be omitted as appropriate. Moreover, the modified examples described below are applicable by being combined with the above-described embodiment or another modified example as appropriate.

### (3.1) First Modified Example

In the above-described example, an aperture shape of the insertion hole 61 is the shape in which both sides in the first direction (long-side direction) are linearly formed and both sides in the second direction (short-side direction) are curved, but is not limited to the shape, and, for example, as illustrated in FIGS. 9A to 9C, may be any shape as long as the distance from the inner peripheral surface to the central axis A1 varies in the circumferential direction.

An insertion hole 61a illustrated in FIG. 9A has an aperture shape in a rectangular shape in which a long-side direction corresponds to the first direction. An insertion hole 61b illustrated in FIG. 9B has an aperture shape in an elliptical shape in which a long-side direction corresponds to the first direction. An insertion hole 61c illustrated in FIG. 9C has an aperture shape in a triangle, and a distance from the central axis A1 to a center of each side is shorter than a distance from the central axis A1 to a vertex. Moreover, the aperture shape of the insertion hole 61 may be a polygon the number of vertexes of which is four or more.

### (3.2) Second Modified Example

In the above-described examples, the aperture shape of the opening 62 is the shape in which both sides in the first direction (long-side direction) are linearly formed and both sides in the second direction (short-side direction) are curved, but is not limited to the shape, and may be other shapes, for example, as illustrated in FIGS. 10A to 11B.

An opening 62a illustrated in FIG. 10A has an aperture shape in a rectangular shape in which a long-side direction corresponds to the first direction. An opening 62b illustrated in FIG. 10B has an aperture shape in a wave shape in which a long-side direction corresponds to the first direction and a center line connecting centers in the second direction that is a short-side direction is wavy. An opening 62c illustrated in FIG. 100 has an aperture shape in a shape obtained by adding a rectangle in which a long-side direction corresponds to the first direction and a round shape which is positioned in a center part of the rectangle. An opening 62d illustrated in FIG. 11A has an aperture shape in a shape obtained by adding a rectangle in which a long-side direction corresponds to the first direction and a pair of round shapes which are positioned at both ends of the rectangle in the long-side direction. An opening 62e illustrated in FIG. 11B has an aperture shape in a curved shape in which both sides extending in the first direction are curved. Specifically, the aperture shape of the opening 62e is a shape in which the both sides extending in the first direction are curved so that distances from the proximal portion 612A of the insertion hole 61 are substantially uniform. In other words, the opening 62e is curved along an outer peripheral edge of the insertion hole 61.

Moreover, without limitation to the shape in which the long-side direction corresponds to the long-side direction (first direction) of the insertion hole 61, the aperture shape of the opening 62 may be a shape in which a long-side direction corresponds to a direction different from the first direction. For example, the opening 62 may have a shape in which a long-side direction corresponds to the short-side direction (second direction) of the insertion hole 61.

In addition, the aperture shape of the opening 62 may be a round shape (perfect circle) in which distances from a central axis are substantially uniform or a polygon (including a square).

Further, as illustrated in FIGS. 12A to 13B, a plurality of openings 62 may be formed in the periphery of the insertion hole 61.

In an example illustrated in FIG. 12A, two openings 62a are formed in the periphery of the proximal portion 612A in the insertion hole 61. The aperture shape of each of the openings 62a is the rectangular shape in which the long-side direction corresponds to the long-side direction (first direction) of the insertion hole 61. The two openings 62a are formed side by side in the long-side direction (first direction) of the insertion hole 61.

In an example illustrated in FIG. 12B, one opening 62a is formed in each of the peripheries of the proximal portions 612A and 612B in the insertion hole 61. The two openings 62a are formed side by side in the short-side direction (second direction) of the insertion hole 61. The insertion hole 61 is formed between the two openings 62a in the second direction.

In an example illustrated in FIG. 12C, a plurality of (in FIG. 12C, three) openings 62a are formed in each of the peripheries of the proximal portions 612A and 612B in the insertion hole 61. The three openings 62a formed in the periphery of the proximal portion 612A are formed so as to surround the proximal portion 612A. The three openings 62a formed in the periphery of the proximal portion 612B are formed so as to surround the proximal portion 612B.

In an example illustrated in FIG. 13A, a plurality of (in FIG. 13A, five) openings 62f are formed in the periphery of the proximal portion 612A in the insertion hole 61. An aperture shape of each of the openings 62f is a rectangular shape in which a long-side direction corresponds to the short-side direction (second direction) of the insertion hole 61. The five openings 62f are formed side by side in the long-side direction (first direction) of the insertion hole 61.

In an example illustrated in FIG. 13B, a plurality of (in FIG. 13B, fifteen) openings 62g are formed in the periphery of the proximal portion 612A in the insertion hole 61. An aperture shape of each of the openings 62g is a round shape (perfect circle) in which distances from a central axis are substantially uniform. The fifteen openings 62g are formed in such a manner that five openings 62g are arranged side by side in the long-side direction (first direction) of the insertion hole 61 and three openings 62g are arranged side by side in the short-side direction (second direction) of the insertion hole 61.

Moreover, in the above-described examples, the opening 62 is a through hole, but is not limited to such a configuration. As illustrated in FIGS. 14A and 14B, an opening 62h may be a concave portion having a bottom. For example, the opening 62h is formed in the upper fixing portion 521 of the upper structure 60A and is a concave portion which has a bottom portion on the front. The opening 62h partially reduces a thickness dimension of the upper fixing portion 521. Thereby, screw stress is suppressed from transferring to a side of the opening 62h opposite to the insertion hole 61. Note that, the opening 62h may be a concave portion which has the bottom portion on the back.

### (3.3) Third Modified Example

The screw attachment member 5 according to a third modified example is illustrated in FIGS. 15A and 15B. In the present modified example, the insertion hole 61 is formed in a bottom portion 603 of a concave portion 602 formed in the structure 60 (upper structure 60A). The concave portion 602 is formed in the upper fixing portion 521 of the upper structure 60A, and has the bottom portion 603 on the front. An aperture shape of the concave portion 602 is a round shape. The insertion hole 61 is formed so as to pass through the bottom portion 603 in the front-back direction.

Moreover, in the present modified example, the opening 62e is formed in the bottom portion 603 of the concave portion 602 together with the insertion hole 61. Note that, the opening 62 (62e) may be formed outside the concave portion 602.

In the present modified example, the insertion hole 61 is formed in the bottom portion 603 of the concave portion 602, so that screw stress outside the concave portion 602 is suppressed from transferring, and deformation of the structure 60 is able to be further suppressed from occurring.

### (3.4) Fourth Modified Example

The screw attachment member 5 is the cabinet 5 in the above-described examples, but may be one other than the cabinet 5.

FIG. 16 illustrates a schematic view of a screw attachment member 5D according to the present modified example. The screw attachment member 5D of the present modified example is a circuit board (hereinafter, also referred to as a circuit board 5D).

The circuit board 5D includes a structure 60D having a rectangular plate shape. The structure 60D has a wiring path formed of a conductive film, and has a plurality of circuit components (for example, a resistance, a capacitor, a coil, and the like) mounted thereon. The structure 60D includes a plurality of (in FIG. 16, six) insertion holes 61 and a plurality of (in FIG. 16, six) openings 62.

The six insertion holes 61 are formed in four corners of the structure 60D and vicinities of center parts of both sides extending in a long-side direction of the structure 60D. Each of the insertion holes 61 is a long hole in which a short-side direction corresponds to a direction connecting the central axis of the insertion hole 61 and a center of the structure 60D.

Each of the openings 62 is formed in a periphery of a corresponding one of the insertion holes 61. The opening 62 is formed between the insertion hole 61 and the center of the structure 60D. The opening 62 is a long hole in which a long-side direction corresponds to the long-side direction (first direction) of the insertion hole 61.

In the present modified example, each of the openings 62 is formed on a side of the center of the structure 60D relative to the insertion hole 61. Therefore, it is possible to suppress deformation of the structure 60D, such as a warp, due to screw stress from occurring.

### (3.5) Another Modified Example

In the above-described examples, the boss 34 passes through the insertion hole 61 and the screw 7 is joined to the boss 34, but there is no limitation thereto. For example, a configuration may be provided such that the screw 7 is joined to the insertion hole 61 in a state where the inner peripheral surface of the insertion hole 61 and the outer peripheral surface of the shaft portion 72 of the screw 7 are in contact.

The present disclosure contains subject matter related to that disclosed in Japanese Priority Patent Application JP 2019-202296 filed in the Japan Patent Office on Nov. 7, 2019, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A screw attachment member comprising
a structure in which
an insertion hole through which a screw passes and
an opening are formed, wherein
in the structure, a peripheral edge portion of the insertion hole is in contact with a bearing surface of a head portion of the screw,
the insertion hole is formed so that a distance between an inner peripheral surface and a central axis of the insertion hole varies in a circumferential direction, and
the opening is formed in a periphery of a proximal portion in the insertion hole at which a distance between the inner peripheral surface and the central axis is shorter than an average.

2. The screw attachment member according to claim 1, wherein
the insertion hole is an elongated hole in which a long-side direction corresponds to a first direction and a short-side direction corresponds to a second direction that is orthogonal to the first direction, and
the opening is formed on a side of the insertion hole in the second direction.

3. The screw attachment member according to claim 2, wherein an aperture of the opening has a shape in which a long-side direction corresponds to the first direction and a short-side direction corresponds to the second direction.

4. The screw attachment member according to claim 2, wherein
an aperture dimension of the opening is greater than an aperture dimension of the insertion hole in the first direction.

5. The screw attachment member according to claim 1, wherein
the opening curves along an outer peripheral edge of the insertion hole.

6. The screw attachment member according to claim 1, wherein
the opening is a through hole that passes through the structure.

7. The screw attachment member according to claim 1, wherein
the structure includes a plurality of openings through which screws pass.

8. The screw attachment member according to claim 1, wherein
the opening is formed between the insertion hole and an end portion in the structure which is proximal to the insertion hole.

9. The screw attachment member according to claim 1, wherein
the structure includes a plurality of insertion holes through which screws pass and a plurality of openings,
the structure is formed so as to be elongated, and
the plurality of insertion holes and the plurality of openings are formed in a long-side direction of the structure.

10. The screw attachment member according to claim 1, wherein
the insertion hole is formed in a bottom portion of a concave portion that is formed in the structure.

11. A display apparatus comprising:
the screw attachment member according to claim 1;
a display unit that includes a display surface, on which an image is displayed, on a front surface and that has a rectangular plate shape; and
a chassis that supports the display unit from a back side, wherein
the screw attachment member is a cabinet surrounding the display unit and is fixed to the chassis by the screw.
